(19) United States
(12) Patent Application Publication
(10) Pub. No.: US 2026/0223651 A1
(43) Pub. Date: Jul. 30, 2026

(54) Power Semiconductor Apparatus and Bonding Method Thereof

(71) Applicant: Diodes Incorporated, Plano, TX (US)

(72) Inventor: Duane Wilcoxen, Plano, TX (US)

(21) Appl. No.: 19/573,931

(22) Filed: Mar. 20, 2026

Related U.S. Application Data
(63) Continuation-in-part of application No. 19/004,306, filed on Dec. 28, 2024.
Application No. 19/004,306 is a division of application No. 18/882,721, filed on Sep. 11, 2024, now Pat. No. 12,308,337.

(51) Int. Cl. H10W 20/00; H10P 14/60; H10W 72/00; H10W 90/00

(52) U.S. Cl. CPC H10W 20/0526; H10W 20/033; H10P 14/6342; H10W 72/0198; H10W 90/734

(57) ABSTRACT

A semiconductor device includes a device wafer comprising a central portion having a first thickness and an edge portion having a second thickness greater than the first thickness, wherein a front side of the central portion is coplanar with a front side of the edge portion, and a backside of the edge portion protrudes beyond a backside of the central portion, and a backside support wafer bonded to the backside of the central portion through an adhesive layer, wherein at least a portion of the backside support wafer is laterally recessed relative to the edge portion of the device wafer such that the portion of the backside support wafer is surrounded by the edge portion of the device wafer.

### PRIORITY

This application is a continuation-in-part of U.S. Patent Application No. 19/004,306, filed on December 28, 2024, entitled “Power Semiconductor Apparatus and Bonding Method Thereof”, which is a divisional of U.S. Patent Application Serial No. 18/882,721, filed on September 11, 2024, now U.S. Patent No. 12,308,337, entitled “Power Semiconductor Apparatus and Bonding Method Thereof,” each of which is hereby incorporated by reference in its entirety.

### TECHNICAL FIELD

The present disclosure relates generally to the field of integrated circuits, and in particular embodiments, to techniques and mechanisms for a thin wafer power semiconductor apparatus.

### BACKGROUND

Since the invention of the integrated circuit, the semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As semiconductor technologies evolve, thin wafer semiconductor devices emerge as an effective alternative to further reduce the physical size of semiconductor chips. For example, thin wafer semiconductor devices are increasingly vital in battery applications where space is at a premium, such as in portable electronics and electric vehicles. These devices leverage ultra-thin silicon or other semiconductor materials to minimize thickness while maintaining high electrical performance. By reducing the wafer thickness, these semiconductors can be integrated into compact battery systems, enhancing energy density without compromising functionality.

In the semiconductor fabrication process, thin wafers present significant challenges due to their instability, lack of flatness, and susceptibility to breakage and stress during processing, all of which can negatively affect device quality. Unsupported thin wafers tend to have a non-planar or wavy profile, making them unsuitable for subsequent fabrication processes that require a flat surface. Additionally, when thin wafers are unsupported during the semiconductor assembly process, they can lead to severe package warpage. This occurs because the inherent stresses in the thin wafer, coupled with the support structure, may cause uneven distribution of forces during packaging. As the wafer is processed, these stresses can become imbalanced, particularly when the wafer is released from its support or subjected to thermal cycling during assembly. This imbalance can result in the entire package bending or warping, which can affect the reliability of the final product, leading to issues such as poor electrical connections, compromised mechanical stability, and reduced overall performance of the semiconductor device. Therefore, there is a clear need for a support assembly that can accommodate thin wafers within existing processing systems. The present disclosure addresses this need.

### SUMMARY

Technical advantages are generally achieved, by embodiments of this disclosure which describe a thin wafer power semiconductor apparatus.

In accordance with an embodiment, a method comprises providing a device wafer having a first side bonded on a supporting wafer, wherein the device wafer comprises a metal layer, a semiconductor substrate, a dielectric layer and a plurality of connectors, providing a carrier, wherein a diameter of the carrier is the same as a diameter of the device wafer, coating an adhesive material onto a second side of the device wafer to form a first adhesive layer, coating the adhesive material onto the carrier to form a second adhesive layer, performing a partial curing process on the first adhesive layer and the second adhesive layer, bonding the device wafer to the carrier through bonding the first adhesive layer and the second adhesive layer together, and performing a full curing process on the adhesive material between the device wafer and the carrier.

In accordance with another embodiment, a device comprises a backside supporting layer having a first thickness, an adhesive layer over the backside supporting layer, a metal layer over the adhesive layer, wherein the metal layer functions as a backside connector, a semiconductor substrate layer over the metal layer, wherein the semiconductor substrate layer has a second thickness, and a plurality of front side connectors, wherein active circuits in the semiconductor substrate layer are electrically coupled between the plurality of front side connectors and the metal layer.

In accordance with yet another embodiment, an apparatus comprises a backside supporting layer having a first thickness; an adhesive layer over the backside supporting layer, a metal layer over the cap layer, wherein the metal layer has a second thickness, and a semiconductor substrate layer over the metal layer, wherein the semiconductor substrate layer has a third thickness, wherein the first thickness of the backside supporting layer is at least four times greater than the third thickness of the semiconductor substrate layer, and the third thickness of the semiconductor substrate layer is greater than the second thickness of the metal layer.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a perspective view of a device wafer and a carrier in accordance with various embodiments of the present disclosure;

FIG. 2 illustrates a perspective view of the device wafer and the carrier after adhesive layers are formed on these two wafers in accordance with various embodiments of the present disclosure;

FIG. 3 illustrates a perspective view of the device wafer and the carrier when a partial curing process is applied to the adhesive layers in accordance with various embodiments of the present disclosure;

FIG. 4 illustrates a perspective view of the bonding of the carrier with the device wafer in accordance with various embodiments of the present disclosure;

FIG. 5 illustrates a perspective view of the device wafer and the carrier after de-bonding the supporting wafer from the device wafer in accordance with various embodiments of the present disclosure;

FIG. 6 is a cross-sectional view of a device chip in accordance with various embodiments of the present disclosure;

FIG. 7 illustrates a flow chart of a method for bonding a device wafer to a carrier in accordance with various embodiments of the present disclosure;

FIG. 8 illustrates a cross-sectional view of a first implementation of bonding the backside support wafer to the device wafer in accordance with various embodiments of the present disclosure;

FIG. 9 illustrates a cross-sectional view of a second implementation of bonding the backside support wafer to the device wafer in accordance with various embodiments of the present disclosure;

FIG. 10 illustrates a flow chart of a first method for bonding a device wafer to a backside support wafer in accordance with various embodiments of the present disclosure; and

FIG. 11 illustrates a flow chart of a second method for bonding a device wafer to a backside support wafer in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely a thin wafer power semiconductor apparatus. The disclosure may also be applied, however, to a variety of power devices. Hereinafter, various embodiments will be explained in detail with reference to the accompanying drawings.

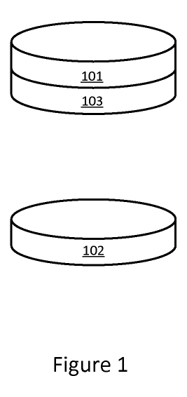

FIG. 1 illustrates a perspective view of a device wafer and a carrier in accordance with various embodiments of the present disclosure. The device wafer 101 is bonded on a supporting wafer 103. The device wafer 101 comprises a metal layer, a semiconductor substrate, a passivation layer and a plurality of connectors. In some embodiments, the passivation layer and the plurality of connectors are on a first side of the semiconductor substrate. The first side is also known as a front side of the semiconductor substrate. The metal layer is on a second side of the semiconductor substrate. The second side is also known as a backside of the semiconductor substrate. Depending on design needs and different applications, a cap layer may be formed over the metal layer. The cap layer is formed of nickel. The metal layer is formed of copper. The nickel cap layer serves as a protective layer that ensures the functionality and longevity of the copper layer. Furthermore, a plurality of dielectric layers and interconnect structures are formed between the semiconductor substrate and the passivation layer. The interconnect structures provide the necessary electrical connections between different components or regions of the device wafer 101.

In some embodiments, the semiconductor substrate has been reduced to a thickness of about 50 micrometers (µm) through suitable semiconductor thinning processes such as a chemical mechanical planarization (CMP) process, a grinding process, an etch back process, any combinations thereof. The metal layer is of a thickness of about 30 µm. The total thickness of the device wafer 101 is about 80 µm. The supporting wafer 103 has a thickness that is greater than the thickness of the device wafer 101. The supporting wafer 103 provides the necessary mechanical stability, allowing the device wafer 101 to withstand the rigors of various semiconductor processing steps.

The carrier 102 is formed of silicon. Alternatively, the carrier 102 is formed of other suitable materials such as glass. In some embodiments, a diameter of the carrier 102 is the same as a diameter of the device wafer 101. The carrier 102 is free from active devices (e.g., transistors) and passive devices (e.g., capacitors, resistors, inductors). Furthermore, the carrier 102 may also be free from conductive lines such as metal lines.

In some embodiments, the device wafer 101 includes a plurality of device chips. The device wafer 101 shown in FIG. 1 is un-sawed, and includes the semiconductor substrate. The semiconductor substrate continuously extends throughout the device wafer 101. In accordance with some embodiments, the semiconductor substrate is formed of a crystalline silicon substrate. Alternatively, the semiconductor substrate may be formed of other semiconductor materials such as silicon germanium, silicon carbon and the like.

In accordance with some embodiments, the device wafer 101 comprises a plurality of active circuits. The active circuits are vertical power devices (e.g., vertical power MOSFET, diodes). The vertical power devices are connected between the metal layer and the plurality of connectors. Alternatively, the active circuits are lateral power devices (e.g., lateral power MOSFET, diodes). The active circuits are formed at the front side of the semiconductor substrate. Furthermore, the active circuits may be logic circuits (e.g., a central processing unit (CPU), graphics processing unit (GPU), system-on-a-chip (SoC), application processor (AP), microcontroller, etc.), memory circuits (e.g., dynamic random access memory (DRAM) dies, static random access memory (SRAM) dies, etc.), power management circuits (e.g., power management integrated circuit (PMIC) dies), radio frequency (RF) circuits, sensor circuits (e.g., image sensors), micro-electro-mechanical-system (MEMS) circuits, signal processing circuits (e.g., digital signal processing (DSP) dies), any combinations thereof and the like.

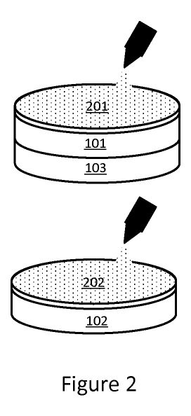

FIG. 2 illustrates a perspective view of the device wafer and the carrier after adhesive layers are formed on these two wafers in accordance with various embodiments of the present disclosure. Through a first spin coating process, an adhesive material is coated on the metal layer of the device wafer 101 to form a first adhesive layer 201. Once the first spin coating process finishes, the thickness of the first adhesive layer 201 is about 15.21 µm. Through a second spin coating process, the adhesive material is also coated on the carrier 102 to form a second adhesive layer 202. Once the second spin coating process finishes, the thickness of the second adhesive layer 202 is about 15.21 µm.

A soft bake process is applied to the first adhesive layer 201 and the second adhesive layer 202 after spin coating. The soft bake process is a thermal treatment process applied to remove residual solvent and improve the adhesion of the first adhesive layer 201 to the metal layer of the device wafer 101, and adhesion of the second adhesive layer 202 to the carrier 102. The specific conditions for the soft bake process can vary depending on design needs. In general, the soft bake process involves heating the coated device wafer and the coated carrier in an oven at a specific temperature for a set amount of time. In some embodiments, the temperature of the soft bake process is about 140 degrees. The soft bake time is about 5 minutes.

In some embodiments, the adhesive material is a polyimide adhesive material. The bonding temperature of the polyimide adhesive material is about 30 degrees. The polyimide adhesive material is in a semi-solid state when the temperature applied to the polyimide adhesive material is less than 160 degrees. The polyimide adhesive material is in a solid state after a full curing process. In some embodiments, the temperature of the full curing process is in a range from about 220 degrees to about 280 degrees. The full curing time is about 2 hours. The thickness of the adhesive layers may change after the full curing process is applied to the adhesive layers. In some embodiments, the thickness of the adhesive layers is about 15.21 µm. After the full curing process, the thickness of the adhesive layers is reduced to about 11.07 µm. The thickness shrinkage rate is about 27.26%.

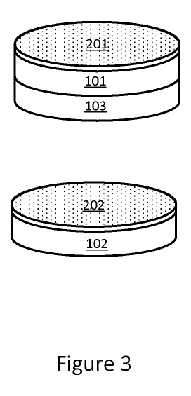

FIG. 3 illustrates a perspective view of the device wafer and the carrier when a partial curing process is applied to the adhesive layers in accordance with various embodiments of the present disclosure. The partial curing process is often used to reduce solvent and moisture content, which can enhance the adhesion and overall strength of the bond. This process typically involves applying heat to the adhesive material to drive off residual solvents and moisture. After the partial curing process, the adhesive material is in a semi-solid state. The material is subjected to higher temperatures to further reduce solvent content and eliminate moisture. This step also helps to cross-link the adhesive materials, enhancing their mechanical properties.

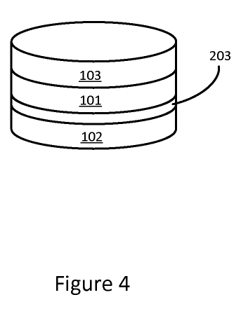

FIG. 4 illustrates a perspective view of the bonding of the carrier with the device wafer in accordance with various embodiments of the present disclosure. In the process of bonding the device wafer 101 to the carrier 102, the adhesive material is in a liquid phase at the bonding temperature.

In operation, after the device wafer is flipped, the two wafers are aligned precisely and brought into contact with each other. The adhesive material flows to fill any gaps between the surfaces, ensuring a uniform bond. The stacked wafers are placed in a vacuum chamber to remove air and prevent void formation within the bond line. Once the vacuum is established, high pressure is applied to the device wafer 101 and the carrier 102. In some embodiments, the bonding pressure is about 1 millibar. Furthermore, a bonding force of 1,000 newtons is used to press the device wafer 101 and the carrier 102 together during the bonding process. The force is applied evenly across the surfaces of the device wafer 101 and the carrier 102 to ensure that the adhesive spreads uniformly, filling any gaps between the device wafer 101 and the carrier 102 to form an adhesive layer 203. This force is essential for ensuring a strong, uniform bond between the device wafer 101 and the carrier 102.

In some embodiments, the temperature of the bonding process is about 30 degrees. The bonding time is about 4 minutes.

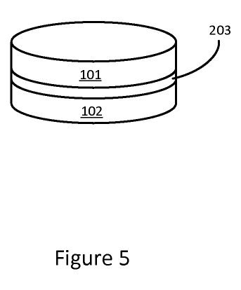

FIG. 5 illustrates a perspective view of the device wafer and the carrier after de-bonding the supporting wafer from the device wafer in accordance with various embodiments of the present disclosure. The supporting wafer 103 is de-bonded from the device wafer 101. The wafer de-bonding can be accomplished using laser-release, solvent-release or thermal-release techniques.

As shown in FIG. 5, after de-bonding the supporting wafer 103 from the device wafer 101, the carrier 102 is left in the final structure.

A full curing process is applied to the adhesive layer 203. The curing process ensures that the adhesive fully polymerizes or cross-links, transitioning from a liquid or a semi-solid state to a solid state. This reaction strengthens the bond between the device wafer 101 and the carrier 102, increasing the mechanical integrity of the final structure. In some embodiments, the temperature of the full curing process is in a range from about 260 degrees to about 280 degrees. The full curing time is about 2 hours.

After a suitable singulation process (e.g., a sawing process), the final structure including the device wafer 101, the adhesive layer 203 and the carrier 102 is divided into many individual device chips, each of which represents a complete, functional unit that can be packaged and used in electronic devices.

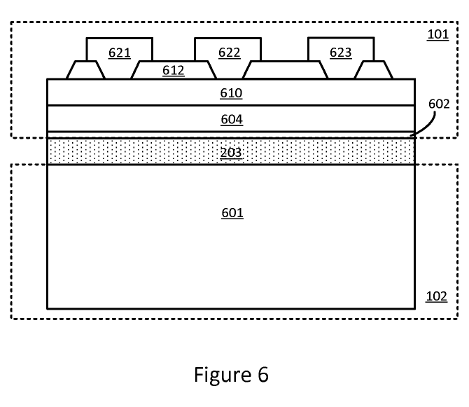

FIG. 6 is a cross-sectional view of a device chip in accordance with various embodiments of the present disclosure. The device chip comprises a backside supporting layer 601, an adhesive layer 203, a cap layer 602, a metal layer 604, the semiconductor substrate 610, a passivation layer 612 and a plurality of connectors 621, 622 and 623.

The backside supporting layer 601 shown in FIG. 6 is one piece of the carrier 102 shown in FIG. 5. As shown in FIG. 6, at a time after the singulation process has been performed, the piece of the carrier 102 is an outermost layer of a corresponding device chip.

The adhesive layer 203 is a dielectric layer formed of a polyimide adhesive material. This polyimide adhesive material has been described above with respect to FIG. 2, and hence is not discussed herein.

The cap layer 602 is formed of nickel. The cap layer serves as a protective layer that ensures the functionality and longevity of the metal layer 604.

The metal layer 604 is formed of copper. The metal layer 604 functions as a backside connector electrically connected to the active circuits in the semiconductor substrate 610. In some embodiments, the active circuits in the semiconductor substrate 610 are a plurality of diodes. The metal layer 604 is electrically connected to cathodes or anodes of the plurality of diodes. In alternative embodiments, the active circuits in the semiconductor substrate 610 are a plurality of back-to-back connected transistors. The metal layer 604 is electrically connected to shared drains or shared sources of the plurality of back-to-back connected transistors.

The semiconductor substrate 610 may be silicon, doped or undoped, or an active layer of a semiconductor-on-insulator substrate. The semiconductor substrate 610 may include other semiconductor materials, such as germanium, silicon carbide, gallium arsenic, gallium phosphide, indium phosphide, indium arsenide, and/or indium antimonide, any combinations thereof and the like.

An inter-layer dielectric (ILD) layer (not shown) may be over the active surface of the semiconductor substrate 610. The ILD layer may include one or more dielectric layers formed of materials such as Phospho-Silicate Glass (PSG), Boro-Silicate Glass (BSG), Boron-Doped Phospho-Silicate Glass (BPSG), undoped Silicate Glass (USG) or the like. The dielectric material may be deposited by spinning, chemical vapor deposition (CVD) or plasma-enhanced CVD (PECVD) techniques.

A plurality of metallization layers (not shown) may be formed over the ILD layer. The metallization layers are used to interconnect various active circuits in the semiconductor substrate 610 and further provide electrical connections between the active circuits and external circuits (not shown).

The passivation layer 612 is formed over the semiconductor substrate 610. The passivation layer 612 may be formed of one or more suitable dielectric materials such as silicon oxide, silicon nitride, low-k dielectrics such as carbon doped oxides, extremely low-k dielectrics such as porous carbon doped silicon dioxide, a polymer such as polyimide, solder resist, polybenzoxazole (PBO), a benzocyclobutene (BCB) based polymer, molding compound, any combination thereof and the like. The passivation layer 612 may be formed by spin coating, lamination, CVD, any combinations thereof and the like.

The connectors 621, 622 and 623 are formed extending through the passivation layer 612 to physically and electrically couple to the semiconductor substrate 610. Alternatively, the connectors 621, 622 and 623 may be electrically coupled to the semiconductor substrate 610 through the interconnect structures in the metallization layers. The connectors 621, 622 and 623 are formed of a conductive material such as aluminum, copper, tungsten, silver, gold, a combination thereof, and/or the like.

In some embodiments, the backside supporting layer 601 has a first thickness in a range from about 200 µm to about 725 µm. The metal layer 604 has a second thickness of about 30 µm. The semiconductor substrate 610 has a third thickness of about 50 µm.

In some embodiments, the total thickness of the device chip shown in FIG. 6 should be less than 200 µm. In order to achieve this thickness, a thinning process is performed on the backside supporting layer 601. The thinning process may be a mechanical grinding process, a chemical polishing process, an etching process or the like. By employing the thinning process, the backside supporting layer 601 can be ground so that the thickness of the backside supporting layer 601 may be reduced from about 725 µm to about 200 µm.

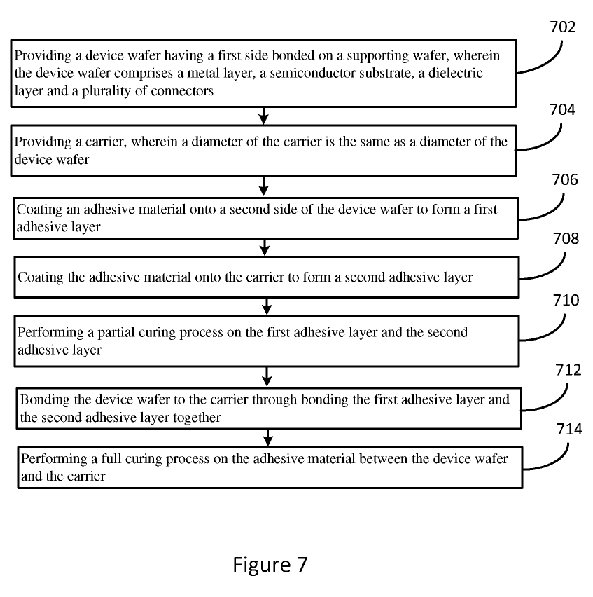

FIG. 7 illustrates a flow chart of a method for bonding a device wafer to a carrier in accordance with various embodiments of the present disclosure. This flowchart shown in FIG. 7 is merely an example, which should not unduly limit the scope of the claims. One of ordinary skill in the art would recognize many variations, alternatives, and modifications. For example, various steps illustrated in FIG. 7 may be added, removed, replaced, rearranged and repeated.

At step 702, a device wafer is provided. The device wafer has a first side bonded on a supporting wafer. The device wafer comprises a metal layer, a semiconductor substrate, a dielectric layer and a plurality of connectors.

At step 704, a carrier is provided. A diameter of the carrier is the same as a diameter of the device wafer.

At step 706, an adhesive material is coated onto a second side of the device wafer to form a first adhesive layer.

At step 708, the adhesive material is coated onto the carrier to form a second adhesive layer.

At step 710, a partial curing process is performed on the first adhesive layer and the second adhesive layer.

At step 712, the device wafer is bonded to the carrier.

At step 714, a full curing process is performed on the adhesive material between the device wafer and the carrier.

The method further comprises after bonding the device wafer to the carrier wafer and before performing the full curing process on the adhesive material, de-bonding the supporting wafer from the device wafer.

The method further comprises after performing the full curing process on the adhesive material, performing a singulation process to separate a plurality of chips in the device wafer into a plurality of packages, wherein each of the plurality of packages comprises a piece of the carrier.

At a time after the singulation process has been performed, the piece of the carrier is an outermost layer of a corresponding package.

The method further comprises at a first temperature, performing the partial curing process on the adhesive material over the second side of the device wafer and the carrier, at a second temperature, bonding the device wafer to the carrier, and at a third temperature, performing the full curing process on the adhesive material, wherein the third temperature is at least 100 degrees higher than the first temperature, and the first temperature is at least 100 degrees higher than the second temperature.

The first temperature is about 140 degrees, the second temperature is about 30 degrees, and the third temperature is about 260 degrees.

Before performing the full curing process on the adhesive material, an adhesive layer between the device wafer and the carrier has a first thickness. After performing the full curing process on the adhesive material, the adhesive layer between the device wafer and the carrier has a second thickness. The metal layer has a third thickness, and wherein the first thickness is greater than the third thickness, and the third thickness is greater than the second thickness.

The adhesive material is a polyimide adhesive material.

The metal layer is in direct contact with the semiconductor substrate, and the metal layer functions as a connector electrically coupled to active circuits in the semiconductor substrate.

The method further comprises bonding the device wafer to the carrier using liquid-phase bonding under high pressure in a vacuum.

In some embodiments, the device wafer 101 is processed using a Taiko grinding technique to obtain a Taiko grind wafer. The Taiko grind wafer refers to a semiconductor wafer that has been thinned in the central region while leaving a thick rim around the perimeter. As such, the device wafer 101 has two portions, namely a central portion and a peripheral rim. The peripheral rim may also be referred to as an edge portion. In some embodiments, the central portion is thinned to a thickness in a range from about 20 micrometers to about 100 micrometers. In some embodiments, the thickness of the central portion of the device wafer 101 is about 55 micrometers. The peripheral rim forms a thicker ring around the wafer edge. In some embodiments, the peripheral rim has a thickness in a range from about 150 micrometers to about 250 micrometers. The peripheral rim provides mechanical strength and rigidity to facilitate wafer handling during subsequent fabrication processes.

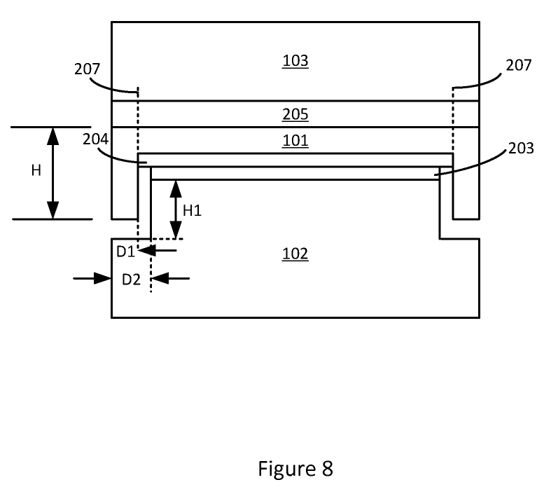

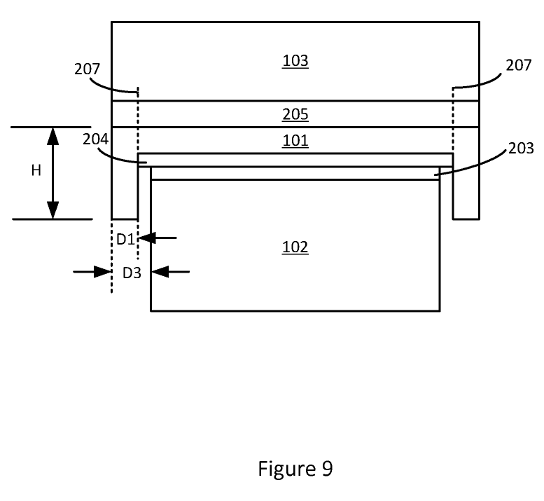

The thinning process applied to the device wafer 101 enables ultra-thin silicon processing while maintaining compatibility with standard wafer handling equipment. However, the raised peripheral rim prevents the use of a conventional backside support wafer in wafer-to-wafer bonding processes. Accordingly, a specially designed support wafer is required to enable bonding with adequate wafer alignment using a bonding adhesive while avoiding the formation of air gaps. Two approaches are proposed to address this issue and to enable strong adhesive bonding with proper wafer alignment. The two approaches are described below with respect to FIGS. 8 and 9, respectively. For ease of describing the inventive aspects, the carrier 102 may also be referred to as a backside support wafer. The supporting wafer 103 may also be referred to as a substrate.

FIG. 8 illustrates a cross-sectional view of a first implementation of bonding the backside support wafer to the device wafer in accordance with various embodiments of the present disclosure. As shown in FIG. 8, the device wafer 101 is bonded to a substrate 103 through a bond tape 205. The device wafer 101 includes a central portion and an edge portion. Dashed lines 207 indicate the boundary between the edge portion and the central portion of the device wafer 101. As shown in FIG. 8, the edge portion has a thickness H that is greater than the thickness of the central portion, thereby forming a raised rim structure around the periphery of the device wafer 101. In some embodiments, H is in a range from about 150 micrometers to about 250 micrometers.

As shown in FIG. 8, a front side of the central portion is coplanar with a front side of the edge portion. A backside of the edge portion protrudes beyond a backside of the central portion. In some embodiments, the edge portion has a radial width D1 measured from an outer peripheral edge of the device wafer 101 to a boundary between the edge portion and the central portion. In some embodiments, D1 is about 2.7 millimeters.

A backside metal layer 204 is formed on the backside of the device wafer 101. An adhesive layer 203 is disposed between the backside metal layer 204 and a backside support wafer 102 so as to bond the backside support wafer 102 to the device wafer 101.

The backside support wafer 102 comprises an upper portion and a lower portion. The upper portion is laterally recessed relative to the outer peripheral edge of the lower portion of the backside support wafer 102. As shown in FIG. 8, the outer peripheral edge of the lower portion is substantially aligned with an outer peripheral edge of the device wafer 101.

A top surface of the lower portion and a sidewall of the upper portion define a recessed region as shown in FIG. 8. The edge portion of the device wafer 101 extends into the recessed region. From the cross-sectional view, the recessed region forms a step. More particularly, the recessed region forms a step around the perimeter of the backside support wafer 102.

In some embodiments, the recessed region has a radial width D2 and a depth of H1. The radial width D2 of the recessed region is defined as a distance between the sidewall of the upper portion and the outer peripheral edge of the lower portion of the backside support wafer 102. The depth of the recessed region is defined as the height of the sidewall of the upper portion of the backside support wafer 102. In some embodiments, D2 is about 4 millimeters. H1 is about 150 micrometers.

The recessed region is configured to receive the edge portion of the device wafer 101 such that the raised rim of the device wafer 101 extends into the recessed region. Due to the greater thickness of the edge portion relative to the central portion of the device wafer 101, the backside of the device wafer 101 forms a cavity bounded by the edge portion. The recessed region of the backside support wafer 102 has dimensions sufficient to accommodate this cavity such that the upper portion of the backside support wafer 102 can fit within the cavity when the backside support wafer 102 is bonded to the central portion of the device wafer 101. The structure shown in FIG. 8 helps maintain wafer alignment and allows the adhesive layer 203 to form a substantially uniform bond without creating air gaps between the device wafer 101 and the backside support wafer 102.

In some embodiments, the recessed region of the backside support wafer 102 may be formed using a plasma etching process. For example, a blanket photoresist layer may be formed on the backside support wafer 102, followed by an edge bead removal (EBR) process to expose a peripheral region having a width of about 4 millimeters. A plasma etch process may then be applied to the exposed silicon to form the recessed region having a depth of about 150 micrometers. In this manner, a step structure is formed near the edge of the backside support wafer 102. In alternative embodiments, the recessed region may be formed using a mechanical process. For example, an edge notch may be created by performing a ring cut using a blade saw at a depth of about 150 micrometers or greater and a width of about 4 millimeters. Other suitable fabrication techniques capable of forming the recessed region may also be used.

The structure shown in FIG. 8 provides several advantageous features. In particular, the edge alignment between the outermost edge of the raised rim and the outermost edge of the backside support wafer 102 enables precise alignment of the backside support wafer 102 relative to the device wafer 101 and the substrate 103. Furthermore, the recessed notch accommodates the raised rim of the device wafer 101 while allowing the bonding process to be performed with a relatively tight spacing between the device wafer 101 and the backside support wafer 102, thereby improving alignment accuracy and facilitating reliable adhesive bonding.

FIG. 9 illustrates a cross-sectional view of a second implementation of bonding the backside support wafer to the device wafer in accordance with various embodiments of the present disclosure. As shown in FIG. 9, the device wafer 101 is bonded to a substrate 103 through a bond tape 205. The device wafer 101 includes a central portion and an edge portion. The edge portion has a thickness H that is greater than the thickness of the central portion, thereby forming a raised rim structure at the periphery of the device wafer 101. In some embodiments, H is in a range from about 150 micrometers to about 250 micrometers. In some embodiments, the edge portion has a radial width D1 measured from an outer peripheral edge of the device wafer 101 to a boundary between the edge portion and the central portion. In some embodiments, D1 is about 2.7 millimeters.

A backside metal layer 204 is formed on a backside of the device wafer 101. An adhesive layer 203 is disposed between the backside metal layer 204 and a backside support wafer 102 so as to bond the backside support wafer 102 to the device wafer 101. In this embodiment, the backside support wafer 102 has a diameter smaller than a diameter of the device wafer 101, such that the backside support wafer 102 is laterally recessed relative to the edge portion of the device wafer 101. As a result, a gap is formed between the edge portion of the device wafer 101 and an outer peripheral edge of the backside support wafer 102. In some embodiments, the distance between the edge portion of the device wafer 101 and the outer peripheral edge of the backside support wafer 102 is denoted as D3. In some embodiments, D3 is about 5 millimeters.

The gap between the edge portion of the device wafer 101 and the backside support wafer 102 functions as an outward flow channel that allows excess adhesive material from the adhesive layer 203 to flow outward during the bonding process. By providing the outward flow channel, excessive adhesive material can escape from the bonding interface, thereby reducing the likelihood of air gaps or voids forming between the device wafer 101 and the backside support wafer 102. In addition, the recessed configuration of the backside support wafer 102 accommodates the protruding edge portion of the device wafer 101, thereby facilitating proper wafer alignment and improving bonding reliability.

In some embodiments, the backside support wafer 102 shown in FIG. 9 can be created using suitable semiconductor fabrication processes such as a silicon etch process, a ring cut blade dicing process and the like.

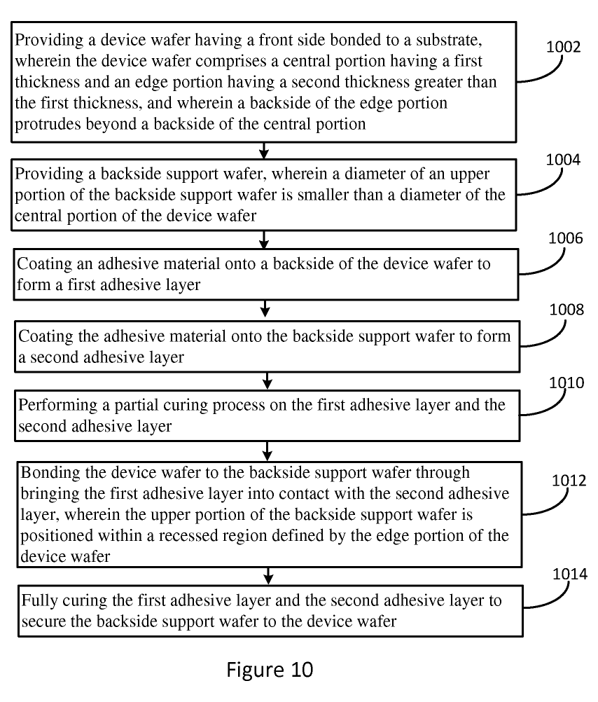

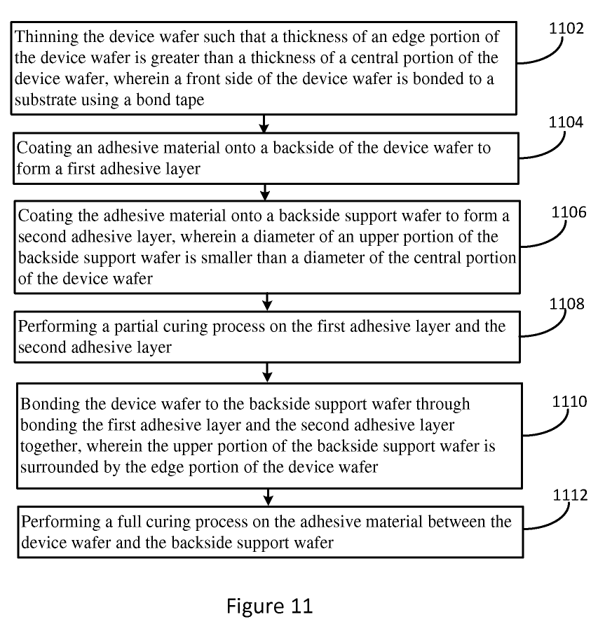

The bonding process described with reference to FIGS. 1-6 is also applicable to the embodiments illustrated in FIGS. 8 and 9. In particular, although the device wafer 101 in FIGS. 8 and 9 includes a raised rim at the edge and the backside support wafer 102 includes a recessed portion or a reduced-diameter portion configured to accommodate the raised rim, the bonding procedure itself may follow the same sequence of steps previously described. Accordingly, the detailed description of each bonding step is not repeated for brevity. FIGS. 10 and 11 illustrate bonding steps corresponding to the embodiments shown in FIGS. 8 and 9.

FIG. 10 illustrates a flow chart of a first method for bonding a device wafer to a backside support wafer in accordance with various embodiments of the present disclosure. This flowchart shown in FIG. 10 is merely an example, which should not unduly limit the scope of the claims. One of ordinary skill in the art would recognize many variations, alternatives, and modifications. For example, various steps illustrated in FIG. 10 may be added, removed, replaced, rearranged and repeated.

At step 1002, a device wafer is provided. The device wafer has a front side bonded to a substrate, wherein the device wafer comprises a central portion having a first thickness and an edge portion having a second thickness greater than the first thickness, and wherein a backside of the edge portion protrudes beyond a backside of the central portion.

At step 1004, a backside support wafer is provided, wherein a diameter of an upper portion of the backside support wafer is smaller than a diameter of the central portion of the device wafer.

At step 1006, an adhesive material is coated onto a backside of the device wafer to form a first adhesive layer.

At step 1008, the adhesive material is coated onto the backside support wafer to form a second adhesive layer.

At step 1010, a partial curing process is performed on the first adhesive layer and the second adhesive layer.

At step 1012, the device wafer is bonded to the backside support wafer through bringing the first adhesive layer into contact with the second adhesive layer, wherein the upper portion of the backside support wafer is positioned within a recessed region defined by the edge portion of the device wafer.

At step 1014, the first adhesive layer and the second adhesive layer are fully cured to secure the backside support wafer to the device wafer.

The method further comprises after bonding the device wafer to the backside support wafer and before performing the full curing process on the adhesive material, de-bonding the substrate from the device wafer, and after performing the full curing process on the adhesive material, performing a singulation process to separate a plurality of chips in the device wafer into a plurality of packages, wherein each of the plurality of packages comprises a piece of the backside support wafer.

In some embodiments, the adhesive material is a polyimide adhesive material.

The method further comprises bonding the device wafer to the backside support wafer using liquid-phase bonding under high pressure in a vacuum.

In some embodiments, the backside support wafer comprises an upper portion and a lower portion, the upper portion is laterally recessed relative to the edge portion of the device wafer, an outer peripheral edge of the lower portion of the backside support wafer is aligned with an outer peripheral edge of the device wafer, a top surface of the lower portion and a sidewall of the upper portion define a recessed region, and the edge portion of the device wafer is received within the recessed region.

In some embodiments, the backside support wafer is laterally recessed relative to the edge portion of the device wafer, and a gap between the edge portion of the device wafer and the backside support wafer forms an outward flow channel configured to allow excess adhesive from the adhesive layer to flow outward during bonding.

FIG. 11 illustrates a flow chart of a second method for bonding a device wafer to a backside support wafer in accordance with various embodiments of the present disclosure. This flowchart shown in FIG. 11 is merely an example, which should not unduly limit the scope of the claims. One of ordinary skill in the art would recognize many variations, alternatives, and modifications. For example, various steps illustrated in FIG. 11 may be added, removed, replaced, rearranged and repeated.

At step 1102, a device wafer is thinned such that a thickness of an edge portion of the device wafer is greater than a thickness of a central portion of the device wafer, wherein a front side of the device wafer is bonded to a substrate using a bond tape.

At step 1104, an adhesive material is coated onto a backside of the device wafer to form a first adhesive layer.

At step 1106, the adhesive material is coated onto a backside support wafer to form a second adhesive layer, wherein a diameter of an upper portion of the backside support wafer is smaller than a diameter of the central portion of the device wafer.

At step 1108, a partial curing process is performed on the first adhesive layer and the second adhesive layer.

At step 1110, the device wafer is bonded to the backside support wafer through bonding the first adhesive layer and the second adhesive layer together, wherein the upper portion of the backside support wafer is surrounded by the edge portion of the device wafer.

At step 1112, a full curing process is performed on the adhesive material between the device wafer and the backside support wafer.

The method further comprises after bonding the device wafer to the backside support wafer and before performing the full curing process on the adhesive material, de-bonding the substrate from the device wafer.

The method further comprises after performing the full curing process on the adhesive material, performing a singulation process to separate a plurality of chips in the device wafer into a plurality of packages, wherein each of the plurality of packages comprises a piece of the backside support wafer.

The method further comprises providing the backside support wafer comprising the upper portion and the lower portion, wherein the upper portion of the backside support wafer is laterally recessed relative to the lower portion of the backside support wafer, aligning an outer peripheral edge of the lower portion with an outer peripheral edge of the device wafer, wherein a top surface of the lower portion and a sidewall of the upper portion define a recessed region, and positioning the device wafer such that the edge portion of the device wafer is received within the recessed region.

The method further comprises laterally recessing the backside support wafer relative to the edge portion of the device wafer, and forming a gap between the edge portion of the device wafer and the backside support wafer, the gap defining an outward flow channel configured to allow excess adhesive to flow outward during bonding.

In accordance with an embodiment, a semiconductor device comprises a device wafer comprising a central portion having a first thickness and an edge portion having a second thickness greater than the first thickness, wherein a front side of the central portion is coplanar with a front side of the edge portion, and a backside of the edge portion protrudes beyond a backside of the central portion, and a backside support wafer bonded to the backside of the central portion through an adhesive layer, wherein at least a portion of the backside support wafer is laterally recessed relative to the edge portion of the device wafer such that the portion of the backside support wafer is surrounded by the edge portion of the device wafer.

Optionally, in the preceding aspect, the backside support wafer is formed of silicon, and wherein the backside support wafer is free from active devices, and the adhesive layer is a dielectric layer formed of a polyimide adhesive material.

Optionally, in any of the preceding aspects, the device wafer comprises a backside metal layer on and in direct contact with the adhesive layer, and a semiconductor substrate on and in direct contact with the backside metal layer.

Optionally, in any of the preceding aspects, an upper portion of the backside support wafer is laterally recessed relative to the edge portion of the device wafer, and an outer peripheral edge of a lower portion of the backside support wafer is aligned with an outer peripheral edge of the device wafer.

Optionally, in any of the preceding aspects, a top surface of the lower portion of the backside support wafer and a sidewall of the upper portion of the backside support wafer together define a recessed region, and the edge portion of the device wafer extends into the recessed region.

Optionally, in any of the preceding aspects, the first thickness is about 55 micrometers, the second thickness is about 150 micrometers, a radial width of the edge portion of the device wafer is about 2.7 millimeters, wherein the radial width is defined as a distance between the outer peripheral edge of the device wafer and a boundary between the edge portion and the central portion of the device wafer, and a radial width of the recessed region is about 4 millimeters, wherein the radial width of the recessed region is defined as a distance between the sidewall of the upper portion and the outer peripheral edge of the lower portion of the backside support wafer.

Optionally, in any of the preceding aspects, the backside support wafer has a smaller diameter than the device wafer.

Optionally, in any of the preceding aspects, a radial width of the edge portion of the device wafer is about 2.7 millimeters, wherein the radial width is defined as a distance between an outer peripheral edge of the device wafer and a boundary between the edge portion and the central portion of the device wafer, and a distance between the outer peripheral edge of the device wafer and an outer peripheral edge of the backside support wafer is about 5 millimeters.

Optionally, in any of the preceding aspects, a gap between the edge portion of the device wafer and the backside support wafer forms an outward flow channel allowing excess adhesive from the adhesive layer to flow outward.

In accordance with another embodiment, a method comprises providing a device wafer having a front side bonded to a substrate, wherein the device wafer comprises a central portion having a first thickness and an edge portion having a second thickness greater than the first thickness, and wherein a backside of the edge portion protrudes beyond a backside of the central portion, providing a backside support wafer, wherein a diameter of an upper portion of the backside support wafer is smaller than a diameter of the central portion of the device wafer, coating an adhesive material onto a backside of the device wafer to form a first adhesive layer, coating the adhesive material onto the backside support wafer to form a second adhesive layer, performing a partial curing process on the first adhesive layer and the second adhesive layer, bonding the device wafer to the backside support wafer through bringing the first adhesive layer into contact with the second adhesive layer, wherein the upper portion of the backside support wafer is positioned within a recessed region defined by the edge portion of the device wafer, and fully curing the first adhesive layer and the second adhesive layer to secure the backside support wafer to the device wafer.

Optionally, in the preceding aspect, the method further comprises after bonding the device wafer to the backside support wafer and before performing the full curing process on the adhesive material, de-bonding the substrate from the device wafer, and after performing the full curing process on the adhesive material, performing a singulation process to separate a plurality of chips in the device wafer into a plurality of packages, wherein each of the plurality of packages comprises a piece of the backside support wafer.

Optionally, in any of the preceding aspects, the adhesive material is a polyimide adhesive material.

Optionally, in any of the preceding aspects, the method further comprises bonding the device wafer to the backside support wafer using liquid-phase bonding under high pressure in a vacuum.

Optionally, in any of the preceding aspects, the backside support wafer comprises an upper portion and a lower portion, the upper portion is laterally recessed relative to the edge portion of the device wafer, an outer peripheral edge of the lower portion of the backside support wafer is aligned with an outer peripheral edge of the device wafer, a top surface of the lower portion and a sidewall of the upper portion define a recessed region, and the edge portion of the device wafer is received within the recessed region.

Optionally, in any of the preceding aspects, the backside support wafer is laterally recessed relative to the edge portion of the device wafer, and a gap between the edge portion of the device wafer and the backside support wafer forms an outward flow channel configured to allow excess adhesive from the adhesive layer to flow outward during bonding.

In accordance with yet another embodiment, a method comprises thinning a device wafer such that a thickness of an edge portion of the device wafer is greater than a thickness of a central portion of the device wafer, wherein a front side of the device wafer is bonded to a substrate using a bond tape, coating an adhesive material onto a backside of the device wafer to form a first adhesive layer, coating the adhesive material onto a backside support wafer to form a second adhesive layer, wherein a diameter of an upper portion of the backside support wafer is smaller than a diameter of the central portion of the device wafer, performing a partial curing process on the first adhesive layer and the second adhesive layer, bonding the device wafer to the backside support wafer through bonding the first adhesive layer and the second adhesive layer together, wherein the upper portion of the backside support wafer is surrounded by the edge portion of the device wafer, and performing a full curing process on the adhesive material between the device wafer and the backside support wafer.

Optionally, in the preceding aspect, the method further comprises after bonding the device wafer to the backside support wafer and before performing the full curing process on the adhesive material, de-bonding the substrate from the device wafer.

Optionally, in any of the preceding aspects, the method further comprises after performing the full curing process on the adhesive material, performing a singulation process to separate a plurality of chips in the device wafer into a plurality of packages, wherein each of the plurality of packages comprises a piece of the backside support wafer.

Optionally, in any of the preceding aspects, the method further comprises providing the backside support wafer comprising the upper portion and the lower portion, wherein the upper portion of the backside support wafer is laterally recessed relative to the lower portion of the backside support wafer, aligning an outer peripheral edge of the lower portion with an outer peripheral edge of the device wafer, wherein a top surface of the lower portion and a sidewall of the upper portion define a recessed region, and positioning the device wafer such that the edge portion of the device wafer is received within the recessed region.

Optionally, in any of the preceding aspects, the method further comprises laterally recessing the backside support wafer relative to the edge portion of the device wafer, and forming a gap between the edge portion of the device wafer and the backside support wafer, the gap defining an outward flow channel configured to allow excess adhesive to flow outward during bonding.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor device comprising:
a device wafer comprising a central portion having a first thickness and an edge portion having a second thickness greater than the first thickness, wherein a front side of the central portion is coplanar with a front side of the edge portion, and a backside of the edge portion protrudes beyond a backside of the central portion; and
a backside support wafer bonded to the backside of the central portion through an adhesive layer, wherein at least a portion of the backside support wafer is laterally recessed relative to the edge portion of the device wafer such that the portion of the backside support wafer is surrounded by the edge portion of the device wafer.

2. The semiconductor device of claim 1, wherein:
the backside support wafer is formed of silicon, and wherein the backside support wafer is free from active devices; and
the adhesive layer is a dielectric layer formed of a polyimide adhesive material.

3. The semiconductor device of claim 1, wherein the device wafer comprises:
a backside metal layer on and in direct contact with the adhesive layer; and
a semiconductor substrate on and in direct contact with the backside metal layer.

4. The semiconductor device of claim 1, wherein:
an upper portion of the backside support wafer is laterally recessed relative to the edge portion of the device wafer; and
an outer peripheral edge of a lower portion of the backside support wafer is aligned with an outer peripheral edge of the device wafer.

5. The semiconductor device of claim 4, wherein:
a top surface of the lower portion of the backside support wafer and a sidewall of the upper portion of the backside support wafer together define a recessed region; and
the edge portion of the device wafer extends into the recessed region.

6. The semiconductor device of claim 5, wherein:
the first thickness is about 55 micrometers;
the second thickness is about 150 micrometers;
a radial width of the edge portion of the device wafer is about 2.7 millimeters, wherein the radial width is defined as a distance between the outer peripheral edge of the device wafer and a boundary between the edge portion and the central portion of the device wafer; and
a radial width of the recessed region is about 4 millimeters, wherein the radial width of the recessed region is defined as a distance between the sidewall of the upper portion and the outer peripheral edge of the lower portion of the backside support wafer.

7. The semiconductor device of claim 1, wherein:
the backside support wafer has a smaller diameter than the device wafer.

8. The semiconductor device of claim 7, wherein:
a radial width of the edge portion of the device wafer is about 2.7 millimeters, wherein the radial width is defined as a distance between an outer peripheral edge of the device wafer and a boundary between the edge portion and the central portion of the device wafer; and
a distance between the outer peripheral edge of the device wafer and an outer peripheral edge of the backside support wafer is about 5 millimeters.

9. The semiconductor device of claim 8, wherein:
a gap between the edge portion of the device wafer and the backside support wafer forms an outward flow channel allowing excess adhesive from the adhesive layer to flow outward.

10. A method comprising:
providing a device wafer having a front side bonded to a substrate, wherein the device wafer comprises a central portion having a first thickness and an edge portion having a second thickness greater than the first thickness, and wherein a backside of the edge portion protrudes beyond a backside of the central portion;
providing a backside support wafer, wherein a diameter of an upper portion of the backside support wafer is smaller than a diameter of the central portion of the device wafer;
coating an adhesive material onto a backside of the device wafer to form a first adhesive layer;
coating the adhesive material onto the backside support wafer to form a second adhesive layer;
performing a partial curing process on the first adhesive layer and the second adhesive layer;
bonding the device wafer to the backside support wafer through bringing the first adhesive layer into contact with the second adhesive layer, wherein the upper portion of the backside support wafer is positioned within a recessed region defined by the edge portion of the device wafer; and
fully curing the first adhesive layer and the second adhesive layer to secure the backside support wafer to the device wafer.

11. The method of claim 10, further comprising:
after bonding the device wafer to the backside support wafer and before performing the full curing process on the adhesive material, de-bonding the substrate from the device wafer; and
after performing the full curing process on the adhesive material, performing a singulation process to separate a plurality of chips in the device wafer into a plurality of packages, wherein each of the plurality of packages comprises a piece of the backside support wafer.

12. The method of claim 10, wherein:
the adhesive material is a polyimide adhesive material.

13. The method of claim 10, further comprising:
bonding the device wafer to the backside support wafer using liquid-phase bonding under high pressure in a vacuum.

14. The method of claim 10, wherein:
the backside support wafer comprises an upper portion and a lower portion;
the upper portion is laterally recessed relative to the edge portion of the device wafer;
an outer peripheral edge of the lower portion of the backside support wafer is aligned with an outer peripheral edge of the device wafer;
a top surface of the lower portion and a sidewall of the upper portion define a recessed region; and
the edge portion of the device wafer is received within the recessed region.

15. The method of claim 10, wherein:
the backside support wafer is laterally recessed relative to the edge portion of the device wafer; and
a gap between the edge portion of the device wafer and the backside support wafer forms an outward flow channel configured to allow excess adhesive from the adhesive layer to flow outward during bonding.

16. A method comprising:
thinning a device wafer such that a thickness of an edge portion of the device wafer is greater than a thickness of a central portion of the device wafer, wherein a front side of the device wafer is bonded to a substrate using a bond tape;
coating an adhesive material onto a backside of the device wafer to form a first adhesive layer;
coating the adhesive material onto a backside support wafer to form a second adhesive layer, wherein a diameter of an upper portion of the backside support wafer is smaller than a diameter of the central portion of the device wafer;
performing a partial curing process on the first adhesive layer and the second adhesive layer;
bonding the device wafer to the backside support wafer through bonding the first adhesive layer and the second adhesive layer together, wherein the upper portion of the backside support wafer is surrounded by the edge portion of the device wafer; and
performing a full curing process on the adhesive material between the device wafer and the backside support wafer.

17. The method of claim 16, further comprising:
after bonding the device wafer to the backside support wafer and before performing the full curing process on the adhesive material, de-bonding the substrate from the device wafer.

18. The method of claim 16, further comprising:
after performing the full curing process on the adhesive material, performing a singulation process to separate a plurality of chips in the device wafer into a plurality of packages, wherein each of the plurality of packages comprises a piece of the backside support wafer.

19. The method of claim 16, further comprising:
providing the backside support wafer comprising the upper portion and the lower portion, wherein the upper portion of the backside support wafer is laterally recessed relative to the lower portion of the backside support wafer;
aligning an outer peripheral edge of the lower portion with an outer peripheral edge of the device wafer, wherein a top surface of the lower portion and a sidewall of the upper portion define a recessed region; and
positioning the device wafer such that the edge portion of the device wafer is received within the recessed region.

20. The method of claim 16, further comprising:
laterally recessing the backside support wafer relative to the edge portion of the device wafer; and
forming a gap between the edge portion of the device wafer and the backside support wafer, the gap defining an outward flow channel configured to allow excess adhesive to flow outward during bonding.
